(19) United States
(12) Patent Application Publication
(10) Pub. No.: US 2009/0152598 A1
(43) Pub. Date: Jun. 18, 2009

(54) BIOSENSOR USING SILICON NANOWIRE AND METHOD OF MANUFACTURING THE SAME

(75) Inventors: In Bok BAEK, Chungcheongbuk-do (KR); Jong Heon Yang, Daejeon (KR); Chang Geun Ahn, Daejeon (KR); Han Young Yu, Daejeon (KR); Chil Seong Ah, Daejeon (KR); Chan Woo Park, Daejeon (KR); An Soon Kim, Daejeon (KR); Tae Youb Kim, Seoul (KR); Moon Gyu Jang, Daejeon (KR); Myung Sim Jun, Daejeon (KR)

Correspondence Address: AMPACC LAW GROUP, 13024 Beverly Park Road, Suite 205, Mukilteo, WA, 98275, US

(73) Assignee: Electronics and Telecommunications Research Institute, Daejeon (KR)

(21) Appl. No.: 12/240,114

(22) Filed: Sep. 29, 2008

(30) Foreign Application Priority Data
Dec. 17, 2007 (KR) 2007-132575

(51) Int. Cl. H01L 29/00; H01L 21/00

(52) U.S. Cl. 257/253; 438/49; 257/E29.001; 257/E21.001

(57) ABSTRACT

Provided are a biosensor using a silicon nanowire and a method of manufacturing the same. The silicon nanowire can be formed to have a shape, in which identical patterns are continuously repeated, to enlarge an area in which probe molecules are fixed to the silicon nanowire, thereby increasing detection sensitivity. In addition, the detection sensitivity can be easily adjusted by adjusting a gap between the identical patterns of the silicon nanowire depending on characteristics of target molecules, without adjusting a line width of the silicon nanowire in the conventional art. Further, the gap between the identical patterns of the silicon nanowire can be adjusted depending on characteristics of the target molecule to differentiate detection sensitivities, thereby simultaneously detecting various detection sensitivities.

### CROSS-REFERENCE TO RELATED APPLICATION

This application claims priority to and the benefit of Korean Patent Application No. 2007-132575, filed Dec. 17, 2007, the disclosure of which is incorporated herein by reference in its entirety.

### BACKGROUND

1. Field of the Invention

The present invention relates to a biosensor using a silicon nanowire and a method of manufacturing the same, and more particularly, to a biosensor capable of enlarging an area of a silicon nanowire to which probe molecules are fixed to increase detection sensitivity and adjusting a line width of the silicon nanowire and a gap between identical patterns to easily adjust the detection sensitivity by forming the silicon nanowire in a manner of continuously repeating the identical patterns, and a method of manufacturing the same.

This work was supported by the IT R&D program of MIC/IITA [2006-S-007-02, Ubiquitous Health Monitoring Module and System Development].

2. Discussion of Related Art

In general, a biosensor is a device for measuring variation depending on biochemical, optical, thermal, or electrical reactions. The latest tendency in research has been toward research on an electrochemical biosensor.

The electrochemical biosensor senses variations of conductivity generated from reactions between a target molecule and a probe molecule in a silicon nanowire to detect a specific biomaterial. The structure and operation of the electrochemical biosensor will be described in detail with reference to FIG. 1.

FIG. 1 is a view showing the structure and operation of a conventional electrochemical biosensor.

Referring to FIG. 1, the conventional electrochemical biosensor 100 includes a semiconductor substrate 10, a source S and a drain D formed on the semiconductor substrate 10, and straight silicon nanowires 13A and 13B disposed between the source S and the drain D. The silicon nanowires 13A and 13B are insulated from the semiconductor substrate 10 and a fluid pipe 31 by an insulating layer 12, and probe molecules 40 are fixed to surfaces of the silicon nanowires 13A and 13B. When target molecules 41 are injected through the fluid pipe 31, the target molecules 41 are coupled to probe molecules 40. An electric field of the silicon nanowires 13A and 13B is varied by the target molecules 41, and therefore, electric potential of the surfaces of the silicon nanowires 13A and 13B is varied to change conductivity of the silicon nanowires 13A and 13B. By observing the variation of the conductivity in real time, it is possible to detect the target molecules 41 injected through the fluid pipe 31.

In the conventional electrochemical biosensor, the silicon nanowires 13A and 13B, to which the probe molecules 40 are fixed, may be formed by a bottom-up method or a top-down method, which has the following disadvantages, respectively.

First, in the bottom-up method, carbon nanotubes grown by a chemical vapor deposition (CVD) method or silicon nanowires formed by a vapor-liquid solid (VLS) growth method are aligned to a specific position to manufacture a biosensor.

While the silicon nanowires formed through the bottom-up type have very good electrical characteristics, the silicon nanowires must be aligned using an electrophoresis method or fluid flow through a fluid channel in order to align the silicon nanowires at a desired position, making it difficult to control the position when the silicon nanowires are aligned.

On the other hand, in the top-down type, the silicon nanowires are formed by a patterning and etching process using CMOS process technology.

However, since electrical characteristics of the silicon nanowires formed by the top-down type are deteriorated in comparison with the nanowires formed by the bottom-up type and most of the nanowires have a simple bar shape, an area to which the probe molecules 30 are fixed may be reduced, making it difficult to increase detection sensitivity. In addition, the fact that the line width and length of the silicon nanowires must be adjusted upon manufacture of the silicon nanowires makes it troublesome to adjust the detection sensitivity of the identical target molecules.

Therefore, a means for increasing detection sensitivity of the electrochemical biosensor using the silicon wires and easily adjusting the detection sensitivity is still needed.

### SUMMARY OF THE INVENTION

The present invention is directed to a biosensor using a silicon nanowire capable of enlarging an area of the silicon nanowire to which a probe molecule is fixed to increase detection sensitivity by forming the silicon nanowire in a manner of continuously repeating the identical patterns.

The present invention is also directed to a biosensor using a silicon nanowire capable of adjusting a gap between identical patterns of the silicon nanowire to easily adjust the detection sensitivity.

The present invention is also directed to a biosensor using a silicon nanowire capable of adjusting a gap between identical patterns of the silicon nanowires depending on characteristics of target molecules to differentiate detection sensitivities, thereby simultaneously detecting various sensitivities.

One aspect of the present invention provides a biosensor including a source electrode and a drain electrode formed on a semiconductor substrate; a silicon nanowire, in which identical patterns are continuously repeated, disposed between the source electrode and the drain electrode; and a probe molecule fixed to the silicon nanowire to react with a target molecule injected from the exterior.

Here, detection sensitivity may be varied depending on a line width of the silicon nanowire and a gap between the identical patterns, and the line width of the silicon nanowire and the gap between the identical patterns may be varied depending on characteristics of the target molecule reacting with the probe molecule. In addition, probe molecules may be fixed to upper/lower and both side surfaces of the silicon nanowire, and therefore, a coupling reaction between the probe molecule and the target molecule may be generated at the upper/lower and both side surfaces of the silicon nanowire.

Another aspect of the present invention provides a method of manufacturing a biosensor including: forming a buffer layer on a semiconductor substrate in which an insulating layer and a silicon layer are sequentially formed; forming an electrode pattern and a silicon nanowire pattern, in which identical patterns are continuously and repeatedly formed, on the buffer layer by a photolithography process; etching the buffer layer and the silicon layer using the electrode pattern and the silicon nanowire pattern as an etching mask; forming an electrode in a region of the electrode pattern; removing the buffer layer formed on the silicon nanowire pattern to expose the silicon nanowire; and fixing probe molecules to the exposed silicon nanowire to react with target molecules injected from the exterior.

Here, a line width of the silicon nanowire and a gap between the identical patterns may be varied depending on detection sensitivity, and the line width of the silicon nanowire and the gap between the identical patterns may be varied depending on characteristics of the target molecule reacting with the probe molecule.

### BRIEF DESCRIPTION OF THE DRAWINGS

The above and other features of the present invention will be described in reference to certain exemplary embodiments thereof with reference to the attached drawings in which:

FIG. 1 is a perspective view showing the structure and operation of a conventional electrochemical biosensor;

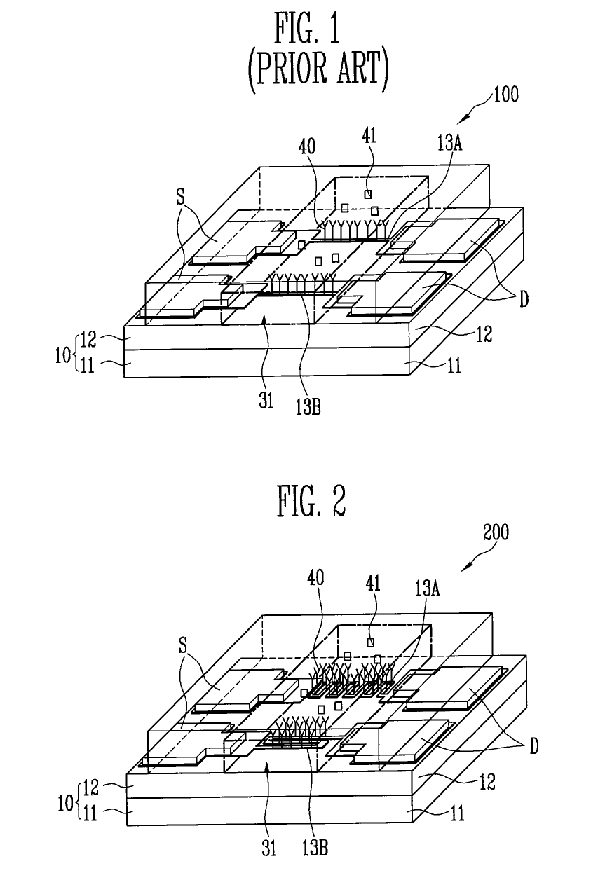

FIG. 2 is a perspective view showing the structure and operation in accordance with an exemplary embodiment of the present invention;

FIG. 3 is a perspective view showing how a probe molecule is coupled to a target molecule in a silicon nanowire in accordance with an exemplary embodiment of the present invention;

FIG. 4 is a flowchart of a method of manufacturing a biosensor in accordance with an exemplary embodiment of the present invention;

FIGS. 5A to 5G are perspective views showing steps of the biosensor manufacturing method in accordance with an exemplary embodiment of the present invention; and

FIGS. 6A and 6B are top views showing silicon nanowires, in which identical patterns are continuously repeated, in accordance with an exemplary embodiment of the present invention.

### DETAILED DESCRIPTION OF EXEMPLARY EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the following description, when it is mentioned that a layer is disposed “on” another layer or a substrate, it means that the layer may be directly formed on the other layer or a third layer may be interposed therebetween. In the drawings, the thickness of layers and regions are exaggerated for clarity. Like reference numerals designate like elements throughout the specification.

A biosensor in accordance with the present invention will now be described in detail with reference to the accompanying drawings.

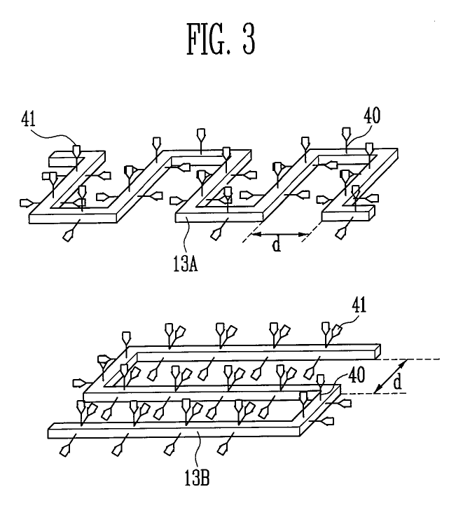

FIG. 2 is a perspective view showing the structure and operation in accordance with an exemplary embodiment of the present invention

Referring to FIG. 2, a biosensor 200 in accordance with an exemplary embodiment of the present invention is similar to the conventional biosensor 100, except that silicon nanowires 13A and 13B are formed in a manner of continuously repeating the identical patterns.

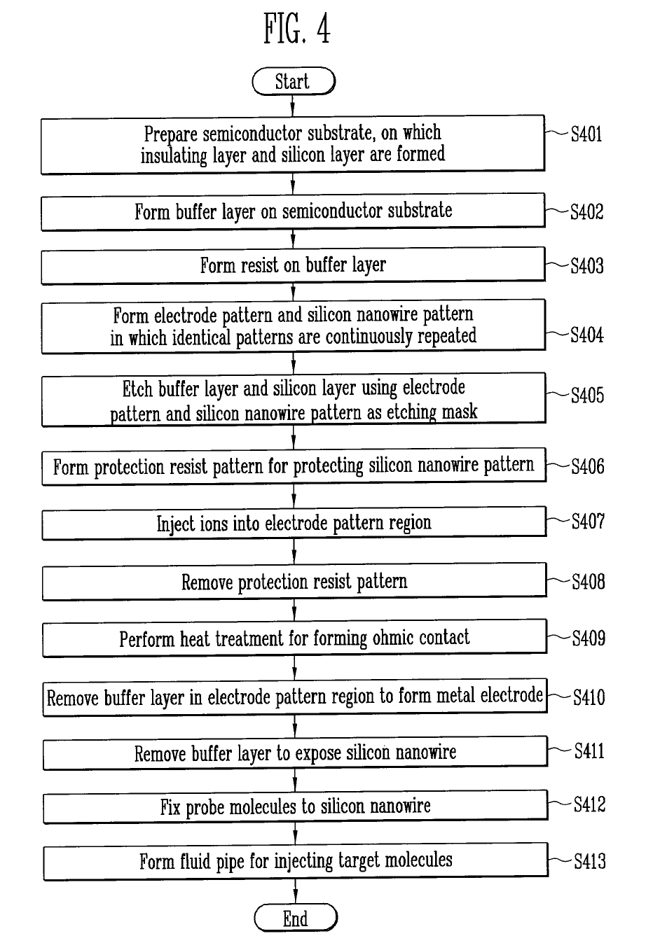

When the silicon nanowires 13A and 13B are formed in a manner of continuously repeating the identical patterns, an area in which probe molecules 40 are fixed to the silicon nanowires 13A and 13B can be enlarged to increase detection sensitivity, and description thereof will be described with reference to FIG. 3.

FIG. 3 is a perspective view showing how probe molecules 40 are coupled to target molecules 41 in the silicon nanowires 13A and 13B in accordance with an exemplary embodiment of the present invention.

Referring to FIG. 3, the target molecules 41 injected through a fluid pipe 31 are coupled to the probe molecules 40 fixed to surfaces of the silicon nanowires 13A and 13B. At this time, the silicon nanowires 13A and 13B are formed in a manner of continuously repeating the identical patterns. When a line width of the silicon nanowires 13A and 13B and a gap d between the identical patterns are reduced, a coupling reaction between the probe molecules 40 and the target molecules 41 are generated at both side surfaces as well as upper and lower surfaces of the silicon nanowires 13A and 13B, thereby overlapping variations of electric fields generated therefrom.

That is, in the biosensor of the present invention, since the silicon nanowires 13A and 13B are formed in a manner of continuously repeating the identical patterns, an area in which the probe molecules 40 are fixed to the silicon nanowires can be enlarged to increase detection sensitivity. In addition, the detection sensitivity can be easily adjusted by adjusting a gap d between the identical patterns of the silicon nanowires 13A and 13B depending on characteristics of the target molecules 41, without adjusting a line width of the silicon nanowires 13A and 13B as in the conventional art. Further, the biosensor in accordance with the present invention may be applied to a sensor array capable of adjusting the gap d between the identical patterns of the silicon nanowires 13A and 13B depending on characteristics of the target molecules 41 to differentiate detection sensitivities, thereby simultaneously detecting various detection sensitivities.

Hereinafter, a method of manufacturing a biosensor in accordance with the present invention will be described in detail with reference to the accompanying drawings.

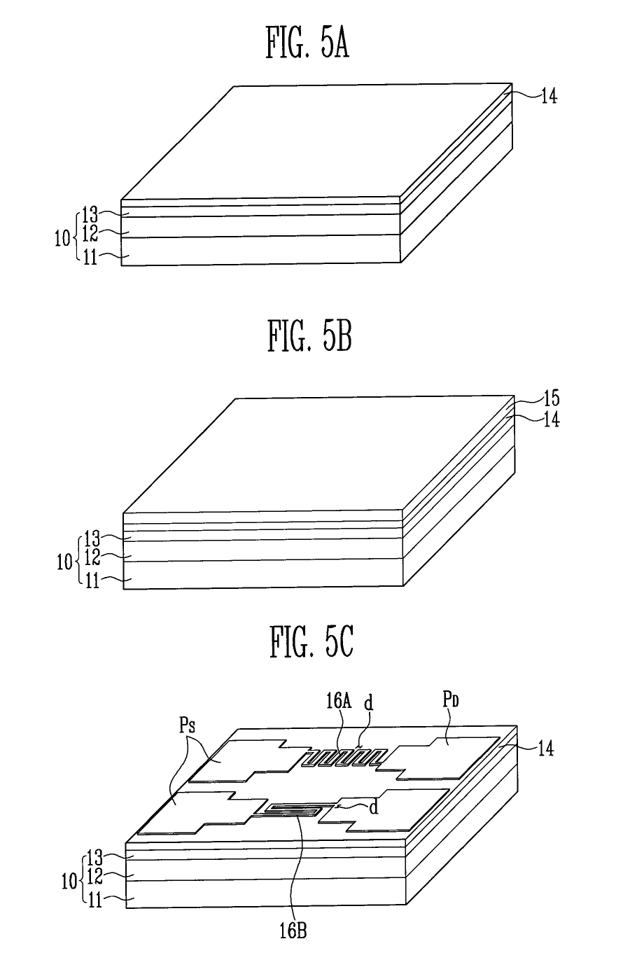

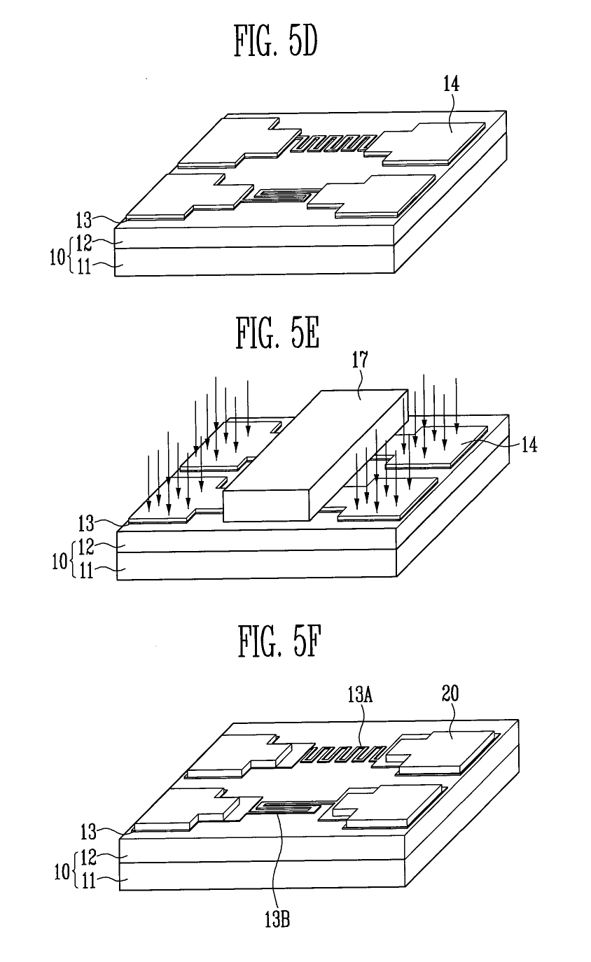

FIG. 4 is a flowchart for explaining a method of manufacturing a biosensor in accordance with an exemplary embodiment of the present invention, and FIGS. 5A to 5G are perspective views showing steps of the biosensor manufacturing method in accordance with an exemplary embodiment of the present invention.

The steps of FIGS. 5A to 5G will be described as follows on the basis of the flowchart of FIG. 4.

First, as shown in FIG. 5A, after preparing a semiconductor substrate 10 in which an insulating layer 12 and a silicon layer 13 are sequentially formed on a silicon wafer 11 (S401), a buffer layer 14 is formed on the semiconductor substrate 10 (S402). The buffer layer 14 may be formed of a nitride film or an oxide film.

Here, a center part of the silicon layer 13 is a region in which silicon nanowires are to be formed. As described above, when the line width of the silicon nanowires are reduced, a coupling reaction between the probe molecules and the target molecules is generated at both side surfaces as well as upper and lower surfaces of the silicon nanowires. Therefore, in order to reduce the line width of the silicon nanowires after forming the buffer layer 14, the thickness of the silicon layer 13, in which the silicon nanowires are to be formed, can be additionally reduced through the following method.

First, a center part of the buffer layer 14 is etched by a photolithography process to expose a region of the silicon layer 13, in which the silicon nanowires are to be formed. Then, the exposed silicon layer 13 is etched, or a thermal oxidation process is used to reduce the thickness of the region of the silicon layer 13, in which the silicon nanowires are to be formed.

Next, as shown in FIG. 5B, a resist 15 for performing electron beam lithography, nano imprint, or photolithography is formed on the buffer layer 14 (S403).

Next, as shown in FIG. 5C, silicon nanowire patterns 16A and 16B are formed by a photolithography process in a manner of continuously repeating the identical patterns as electrode patterns Ps and Pd (S404). Here, the silicon nanowire patterns 16A and 16B may be varied in various manners under the condition that the identical patterns are continuously repeated, and the gap d between the identical patterns may be 5 to 200 nm.

Next, as shown in FIG. 5D, the buffer layer 14 and the silicon layer 13 are etched using the electrode patterns Ps and Pd and the silicon nanowires 16A and 16B as an etching mask (S405).

Next, as shown in FIG. 5E, after forming a protection resist pattern 17 for protecting the silicon nanowire patterns 16A and 16B by a photolithography process (S406), ions are injected into the electrode patterns Ps and Pd (S407). Then, the protection resist pattern 17 for protecting the silicon nanowire patterns 16A and 16B is removed (S408), and heat treatment for forming an ohmic contact is performed (S409).

Next, as shown in FIG. 5F, the buffer layer 14 formed in regions of the electrode patterns Ps and Pd is selectively removed by a photolithography process to form metal electrodes 20 (S410). Then, the buffer layer 14 covering the silicon nanowire patterns 16A and 16B is selectively removed to expose silicon nanowires 13A and 13B (S411). Next, as shown in FIG. 5G, probe molecules 40 are fixed to the silicon nanowires 13A and 13B (S412), and a fluid pipe for injecting target molecules 41 is formed (S413).

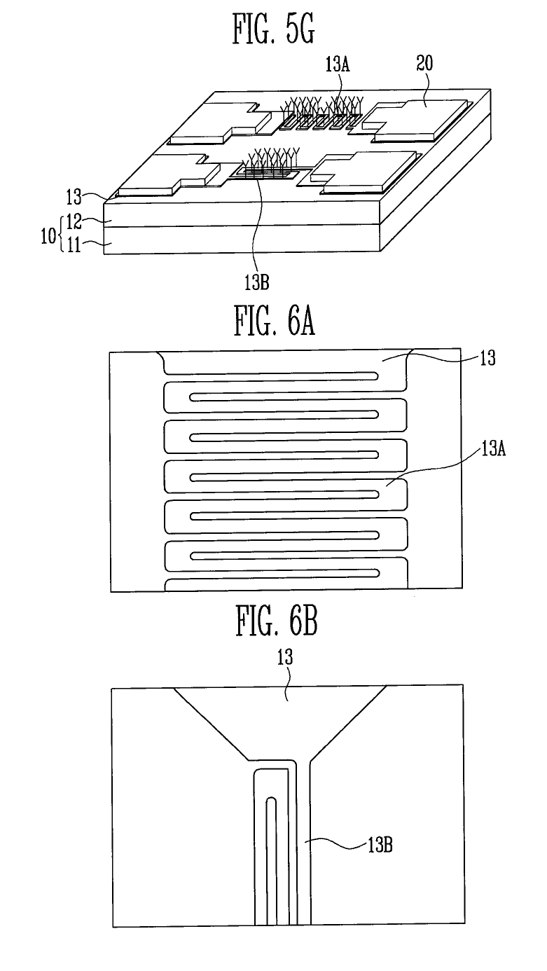

That is, the silicon nanowires 13A and 13B in which identical patterns are continuously repeated are formed through the above processes, and results thereof are shown in FIGS. 6A and 6B.

FIGS. 6A and 6B are top views showing silicon nanowires 13A and 13B, in which identical patterns are continuously repeated, in accordance with an exemplary embodiment of the present invention. As shown in FIGS. 6A and 6B, the silicon nanowires 13A and 13B in accordance with the present invention have a shape in which identical patterns are continuously repeated in a direction perpendicular or parallel to the fluid pipe.

As described above, when the silicon nanowires 13A and 13B are formed in a manner of continuously repeating the identical patterns, the area in which the probe molecules 40 are fixed to the silicon nanowires 13A and 13B can be enlarged to increase detection sensitivity, and a description thereof will not repeated because it has been described in detail with reference to FIG. 3.

As can be seen from the foregoing, a silicon nanowire is formed to have a shape, in which identical patterns are continuously repeated, to enlarge an area in which probe molecules are fixed to the silicon nanowire, thereby increasing detection sensitivity.

In addition, in accordance with the present invention, the detection sensitivity can be easily adjusted by adjusting a gap between the identical patterns of the silicon nanowire depending on characteristics of a target molecule, without adjusting a line width of the silicon nanowire as in the conventional art.

Further, the gap between the identical patterns of the silicon nanowire can be adjusted depending on characteristics of the target molecule to differentiate detection sensitivities, thereby simultaneously detecting various detection sensitivities.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. A biosensor using a silicon nanowire, comprising:
a source electrode and a drain electrode formed on a semiconductor substrate;
a silicon nanowire, in which identical patterns are continuously repeated, disposed between the source electrode and the drain electrode; and
probe molecules fixed to the silicon nanowire to react with target molecules injected from the exterior.

2. The biosensor according to claim 1, wherein the probe molecules are fixed to upper/lower and both side surfaces of the silicon nanowire, and a coupling reaction between the probe molecule and the target molecule is generated at the upper/lower and both side surfaces of the silicon nanowire.

3. The biosensor according to claim 1, wherein detection sensitivity is varied depending on a gap between the identical patterns of the silicon nanowire.

4. The biosensor according to claim 1, wherein a line width of the silicon nanowire and a gap between the identical patterns are varied depending on characteristics of the target molecules reacting with the probe molecules.

5. The biosensor according to claim 1, wherein a gap between the identical patterns of the silicon nanowire is 5 to 200 nm.

6. The biosensor according to claim 1, wherein when gaps between the identical patterns of the silicon nanowire are different from each other, at least one sensitivity is simultaneously detected.

7. The biosensor according to claim 1, further comprising:
a fluid pipe for injecting the target molecules.

8. A method of manufacturing a biosensor using a silicon nanowire, comprising:
forming a buffer layer on a semiconductor substrate in which an insulating layer and a silicon layer are sequentially formed;
forming an electrode pattern and a silicon nanowire pattern, in which identical patterns are continuously and repeatedly formed, on the buffer layer by a photolithography process;
etching the buffer layer and the silicon layer using the electrode pattern and the silicon nanowire pattern as an etching mask;
forming an electrode in a region of the electrode pattern;
removing the buffer layer formed on the silicon nanowire pattern to expose the silicon nanowire; and
fixing probe molecules to the exposed silicon nanowire to react with target molecules injected from the exterior.

9. The method according to claim 8, wherein the buffer layer is formed of a nitride layer or an oxide layer.

10. The method according to claim 8, wherein the electrode pattern and the silicon nanowire pattern are formed by any one process selected from electron beam lithography, nano imprint, and photolithography.

11. The method according to claim 8, wherein the forming a silicon nanowire pattern further comprises varying a line width of the silicon nanowire and a gap between the identical patterns depending on detection sensitivity.

12. The method according to claim 8, wherein the forming a silicon nanowire pattern further comprises varying a line width of the silicon nanowire and a gap between the identical patterns depending on characteristics of the target molecules reacting with the probe molecules.

13. The method according to claim 8, wherein a gap between the identical patterns of the silicon nanowire pattern is 5 to 200 nm.

14. The method according to claim 8, further comprising:
after the forming a buffer layer and before the forming an electrode pattern and a silicon nanowire pattern,
selectively etching the buffer layer corresponding to a region, in which the silicon nanowire is to be formed, by a photolithography process to expose a region of the silicon layer in which the silicon nanowire is to be formed; and
reducing the thickness of the region of the silicon layer, in which the silicon nanowire is to be formed, by an etching or thermal oxidation process.

15. The method according to claim 8, wherein the forming an electrode comprises:
forming a protection resist pattern for protecting the silicon nanowire pattern by a photolithography process;
injecting ions into the electrode pattern region;
removing the protection resist pattern;
performing heat treatment to form an ohmic contact in the electrode pattern region; and
removing the buffer layer in the electrode pattern region by a photolithography process to form a metal electrode.

16. The method according to claim 8, further comprising:
forming a fluid pipe for injecting the target molecules.
